(19) United States
(12) Patent Application Publication
(10) Pub. No.: US 2013/0075134 A1
(43) Pub. Date: Mar. 28, 2013

(54) PREPARING A SUBSTRATE FOR EMBEDDING WIRE

(71) Applicant: David Finn, Tourmakeady (IE)

(72) Inventor: David Finn, Tourmakeady (IE)

(73) Assignee: Feinics AmaTech Nominee Limited, Tourmakeady (IE)

(21) Appl. No.: 13/430,739

(22) Filed: Mar. 27, 2012

Related U.S. Application Data
(63) Continuation-in-part of application No. 12/901,590, filed on Oct. 11, 2010.
Application No. 12/901,590 is a continuation-in-part of application No. 13/294,578, filed on Nov. 11, 2011.
Application No. 13/294,578 is a continuation-in-part of application No. 13/224,351, filed on Sep. 2, 2011.
(60) Provisional application No. 61/493,448, filed on Jun. 4, 2011.
(60) Provisional application No. 61/493,611, filed on Jun. 6, 2011.

(51) Int. Cl. H01P 11/00; H05K 1/02

(52) U.S. Cl. CPC H01P 11/00; H05K 1/0298
USPC 174/250; 29/601

(57) ABSTRACT

A portion of the surface of a substrate may be prepared for mounting an antenna wire such as by removing material to form a sequence of ditches (holes) separated by bridges (lands), and conforming to the pattern for the antenna, which is typically a flat squared spiral, having a number of turns. The antenna wire may be laid in the ditches and embedded in the bridges. Additional features, such as undermining or removing material from adjacent the bridges may facilitate displacement of substrate material at the bridges. The collapsed bridges form pinch points, securing the wire in the substrate. In some embodiments of the invention, relevant portions of the substrate are prepared for embedding antenna wire, without removing material. The substrate may be an inlay substrate or card body for a secure document.

### TECHNICAL FIELD

The invention relates to embedding wire in substrates, such as inlay substrates for “secure documents” such as electronic passports, electronic ID cards and smart cards having RFID (radio frequency identification) chips or chip modules, the embedded wire typically being laid in a flat spiral pattern on the substrate and connected with the RFID chip and functioning as an antenna for interacting with an external RFID reader.

### BACKGROUND

An “inlay” (or “transponder”) may be incorporated into secure documents such as “smart cards”, national ID cards and “electronic passports” using RFID technology, and may comprise:
an inlay substrate comprising a plurality of transponder sites,
an antenna (typically in the form of a flat coil) comprising a few turns of conductor,
an RFID chip (or chip module) disposed on or in (typically in a recess in) the inlay substrate, wherein “terminal ends” (termination ends, end portions, connection portions) of the antenna wire are connected (bonded) to “terminal areas” (terminals, contact pads) of the chip module.

When “inlay substrate” is referred to herein, it should be taken to include “card body”, and vice versa, unless explicitly otherwise stated.

FIGS. 1A and 1B illustrate an inlay comprising an inlay substrate, a chip module and an antenna, such as disclosed in U.S. Pat. No. 6,233,818, incorporated by reference herein.

The inlay substrate may comprise one or more layers of Polyvinyl Chloride (PVC), Polycarbonate (PC), Polyethylene (PE), PET (doped PE), PET-G (derivative of PE), Coated Fleece, Teslin™, Paper or Cotton/Noil, and the like. For example, a single layer of uncoated Teslin™, with a thickness of 356 microns. In the main hereinafter, inlay substrates comprising Teslin™ or Polycarbonate (PC) will be described.

The antenna conductor may be self-bonding (or self-adhering) wire comprising; a metallic core (typically, but not necessarily round in cross-section) comprising copper, aluminum, doped copper, gold, or Litz wire, and may have a diameter of 0.010-0.50 mm; a first coating or “base coat” comprising modified polyurethane, and having a thickness of only a few microns; and a second coating comprising polyvinylbutyral or polyamide, and having a thickness of only a few microns. Other forms of antenna conductor which are not wires may be discussed herein.

The chip module may be a leadframe-type chip module or an epoxy glass type chip module. In the main hereinafter, leadframe-type chip modules are discussed, which may comprise an RFID chip encapsulated by a mold mass and supported by and connected to a leadframe having two terminal areas. The mold mass may be approximately 240 μm thick and 5 mm wide, the leadframe may be approximately 80 μm thick and 8 mm wide. The total thickness of the leadframe module may be 320 μm, such as for an inlay substrate having a thickness of approximately 356 μm. Generally, the chip module will be disposed in a recess in the inlay substrate so as to be concealed therein.

The recess (or cavity) for receiving the chip module may extend into the inlay substrate from a “top” surface thereof, and may be a “window” type recess extending completely through the inlay substrate to a “bottom” surface thereof, or the recess may be a “pocket” type recess extending only partially through the inlay substrate towards the bottom surface thereof. The recess may have a “straight” profile, or it may have a “stepped” profile. The recess is generally sized and shaped to accommodate the size and shape of the chip module being disposed therein.

A conventional method of mounting an antenna wire to an inlay substrate is to use a sonotrode (ultrasonic) tool which vibrates, feeds the wire out of a capillary, and embeds it into or sticks it onto the surface of the inlay substrate, in the form of a flat coil, with ends or end portions of the antenna wire connected, such as by thermo compression (TC) bonding, to terminal areas of the chip module. See U.S. Pat. No. 6,698,089 and U.S. Pat. No. 6,233,818, incorporated by reference herein.

A typical pattern for an antenna is generally rectangular, in the form of a flat (planar) coil (spiral) having a number of turns. The two ends of the antenna wire may be connected, such as by thermo-compression (TC) bonding, to terminals (or terminal areas, or contact pads) of the chip module. In some secure documents, bare semiconductor dies (chips) may be used, rather than chip modules.

FIGS. 1A and 1B illustrate an example of a prior art technique for mounting an antenna wire 110 to an inlay substrate 102 and connecting the antenna wire to a chip module 108 installed in a recess 106 in the inlay substrate (at a transponder site). An inlay sheet 100 may comprise a plurality of transponder sites, only one of which is shown in some detail. The dashed lines in FIG. 1A indicate that there may be other transponder sites above, below, to the left or to the right of the illustrated transponder site.

A pocket-type recess 106 is formed in the inlay substrate 102 for receiving a leadframe-type RFID chip module 108, positioned with the mold mass 112 situated below a leadframe 114.

The inlay substrate 102 is shown as a single layer substrate, but it may comprise two or more layers. The leadframe 114 of the chip module 108 has two terminal areas 108a and 108b. An antenna wire 110 is mounted to the inlay substrate 102 and is connected to the terminal areas 108a and 108b of the chip module 108 by its termination ends (connection portions, ends, end portions).

The wire 110 may be mounted to the inlay substrate 102 by embedding (as indicated by the symbols “x”) between the points “a” and “b”, then passing over the first terminal 108a of the chip module 108 between the points “b” and “c” (without embedding), then embedding to form the turns of the antenna between the points “c” and “d”, then passing over the second terminal 108b of the chip module 108 between the points “d” and “e”, then embedded a short distance between the points “e” and “f”. The antenna may comprise 4 or 5 turns of wire, and the overall length of the antenna wire 110 may be approximately 104 cm. In forming the turns of the antenna, the wire may need to cross over itself (dashed circle, “k”), thus requiring an insulated wire. In some cases, the antenna wire does not need to cross over itself. See, for example, FIG. 4 of U.S. Pat. No. 6,698,089. The embedding process (such as between the points “c” and “d”) may be discontinuous, at several points, rather than continuous. In a next (second) stage of the process, the “connection” portions of the antenna wire 110 passing over the terminal areas 108a and 108b are interconnected thereto, such as by means of thermo compression bonding. It is known to remove insulation from the connection portions of the antenna wire to improve bonding. Since it is difficult to embed in Teslin™, it is known to use “self-bonding” wire which attaches with a slight penetration of the wire in the material.

U.S. Pat. No. 6,233,818 (Finn et al., 2001), incorporated by reference herein, discloses using an ultrasonic tool to embed wire into a surface of an inlay substrate. During embedding, material is displaced. The material will exhibit a resistance to displacement. Consequently, this process works better with some substrate materials than with others. The antenna wire is relatively easily embedded in a “soft” material such as PVC. Embedding the antenna wire in a “harder”, or porous material such as Teslin™ can be difficult.

U.S. Pat. No. 7,028,910 (Schlumberger, 2006), incorporated by reference herein, discloses forming housings (channels) for the turns of the antenna, and placing a conducting material in the housing(s), the conducting material forming an antenna for an object such as a phone card. The housing(s) may be made by machining, laser, molding, hot pressing, etc. The antenna may be formed from a conducting wire, and the housings avoid any short circuiting by contact between the various turns of the antenna. The geometry of the antenna is also more precisely defined. In particular the distance between the different turns is more precisely defined. The cross-section of the individual housings is preferably semi-circular. The antenna can also be made with by filling the housing(s) with a conducting resin.

In either case—namely, embedding as in U.S. Pat. No. 6,233,818 or disposing the antenna wire in channels as in U.S. Pat. No. 7,028,910—the goals are to facilitate mounting the antenna wire on the substrate so that it resides below the surface of the substrate into which it is mounted, and stays put during subsequent manufacturing steps. Although the technique of first forming channels substantially eliminates problems with embedding the wire be displacing material, a problem with first forming a channel for the wire is that the antenna wire may not be securely retained within the channel(s), and may become dislodged during subsequent handling of the substrate (prior to final laminating). As mentioned in U.S. Pat. No. 7,028,910, means may be used to hold the antenna in the housing. These means may be adhesive material or a special coating which is applied in the individual housings to make sure that the antenna fitted afterwards is held firmly.

### SUMMARY

According to the invention generally, a portion of the surface of a substrate for a secure document is prepared for embedding an antenna wire therein. The pattern of the antenna wire is typically a flat squared spiral, having a number (such as 4 or 5) of turns.

According to an embodiment of the invention generally, the surface of a substrate may be prepared for mounting an antenna wire by creating a series of ditches interrupted by bridges, along a path which will be the pattern or contour for the antenna. When mounting the wire, the force of the ultrasonic tool will break these bridges when embedding the wire into the substrate. And the wire sinks completely into the material such as Teslin™. This avoids the need to create a full channel, corresponding with the pattern of the antenna.

Laser ablation may be used to remove material at intervals in the pattern, such as ablating a sequence of trenches or ditches (extending into the surface of the substrate) separated by bridges or lands (substantially unablated substrate material between successive trenches).

The trenches may be approximately the same width and depth as the wire diameter so that the antenna wire may simply be placed (laid) in the trenches (such as in the manner of U.S. Pat. No. 7,028,910). When encountering bridges, the wire is embedded into the substrate material at the location of the bridges, displacing substrate material (such as in the manner of U.S. Pat. No. 6,233,818).

For an antenna pattern of a given length, the object is to substantially reduce the amount of substrate material that needs to be embedded/displaced. For example, whereas in U.S. Pat. No. 6,233,818, material needs to be displaced along substantially 100% of the antenna pattern, by removing material at intermittent locations (at the trenches), less material needs to be displaced (at the bridges). For example, the prepared antenna pattern having a length “L” may comprise a plurality of “n” trenches having a nominal length “L1” separated by “n” (or n−1, or n+1) bridges each having a nominal length “L2”. Generally, L=nL1+nL2.

When the antenna wire is embedded in the bridges separating the trenches, the bridges will collapse or be displaced, and may retain the wire by an interference fit. The bridges may be prepared by removing some material at the surface of the substrate, such as to a depth of only a fraction (such a 20%-30%) of the diameter of the wire, thereby making it a little easier for the substrate material at the bridges to be displaced during embedding. Generally, the height of such prepared bridges ought to be at least 50% of the diameter of the antenna wire, to facilitate the interference fit.

The trenches may be formed to have a depth which is slightly less (such as 80%-90%) than the diameter of the wire, in which case the antenna wire can be embedded somewhat in the bottoms of the trenches.

According to other embodiments of the invention, additional features may be created to facilitate displacement of substrate material at the bridges, during embedding. This may include slits or slots adjacent the bridges. A serpentine channel may have portions within which wire is laid, and other portions which deviate from the antenna pattern but which facilitate embedding.

According to other embodiments of the invention, relevant portions of the substrate are prepared for embedding antenna wire, without removing material.

Other objects, features and advantages of the invention may become apparent in light of the following description(s) thereof.

### BRIEF DESCRIPTION OF THE DRAWINGS

Reference will be made in detail to embodiments of the disclosure, non-limiting examples of which may be illustrated in the accompanying drawing figures (FIGS). The figures are generally diagrams. Some elements in the figures may be exaggerated, others may be omitted, for illustrative clarity. Although the invention is generally described in the context of various exemplary embodiments, it should be understood that it is not intended to limit the invention to these particular embodiments, and individual features of various embodiments may be combined with one another.

FIG. 1A is a top view of a transponder site on an inlay substrate, according to the prior art.

FIG. 1B is a cross-sectional view illustrating a wire being mounted to an inlay substrate and the wire being bonded to the terminals of a chip module, according to the prior art.

FIG. 2A is a partial perspective view showing forming a recess in a substrate.

FIG. 2B is a partial cross-sectional view showing forming a channel in a substrate, and laying a wire in the channel.

FIG. 2C is a partial top view of a recess and channels extending from edges of the recess.

FIG. 2D is a partial perspective view of channels crossing each other in a substrate.

FIG. 2E is a cross-sectional view of a technique for forming features such as profiled channels for mounting an antenna wire in an inlay substrate.

FIG. 3A is a top view of a “square spiral” pattern for receiving an antenna wire in a substrate.

FIG. 3B is a cross-sectional view of channel portions (2 shown) formed in the substrate of FIG. 3A, taken on a line 3B-3B through FIG. 3A.

FIG. 3C is a top view of a technique for forming “ditches” and “bridges” for receiving an antenna wire in a substrate, according to an embodiment of the invention.

FIGS. 3D and 3E are top views of a technique for forming “holes” and “lands” for receiving an antenna wire in a substrate, according to an embodiment of the invention.

FIG. 3F is a cross-sectional view of a technique for forming perforations in a layer of a multi-layer substrate, according to an embodiment of the invention.

FIG. 3G is a cross-sectional view of a technique for forming “ditches” and “bridges” for receiving an antenna wire in a substrate, according to an embodiment of the invention.

FIG. 3H is a cross-sectional view of a technique for forming “holes” and “lands” for receiving an antenna wire in a substrate, according to an embodiment of the invention.

FIG. 3I is a cross-sectional view of a technique for forming a modified channel for receiving an antenna wire in a substrate, according to an embodiment of the invention.

FIG. 4A is a cross-sectional view illustrating forming channels in a substrate, such as for receiving individual turns of an antenna structure.

FIG. 4B is a cross-sectional view illustrating forming a wide trench in a substrate, such as for receiving an antenna structure, according to an embodiment of the invention.

FIG. 4C is a cross-sectional view of an antenna structure being installed in a wide trench, according to an embodiment of the invention.

FIG. 4D is a cross-sectional view of an antenna structure having several turns being installed in a wide trench, and a portion of the antenna wire crossing over the several turns of the antenna structure, according to an embodiment of the invention.

FIG. 4E is a cross-sectional view of a technique for modifying substrate material in a “pattern” for receiving individual turns of an antenna wire in a substrate, according to an embodiment of the invention.

FIG. 4F is a cross-sectional view of a technique for modifying substrate material for receiving an antenna structure having several turns of wire in a substrate, according to an embodiment of the invention.

FIG. 4G is a top view of a “hybrid” technique for forming “ditches” and “bridges” for receiving an antenna wire in a substrate, and also modifying the substrate in the “pattern”, according to an embodiment of the invention.

FIG. 4G is a top view of a technique for modifying the substrate in the “pattern”, according to an embodiment of the invention.

FIG. 5A is a perspective view of an inlay substrate.

FIG. 5B is a top view of the inlay substrate of FIG. 5A.

FIG. 5C is a top view of an inlay substrate.

FIG. 6A is a top view of an inlay for a passport.

FIG. 6B is a cross-sectional view of the inlay of FIG. 6A, taken on a line 6B-6B.

### DETAILED DESCRIPTION

The invention relates generally to inlays and techniques for making the inlays for “secure documents”. As used herein, an “inlay” may be a single- or multi-layer substrate containing HF (high frequency) and/or UHF (ultra-high frequency) radio frequency identification (RFID, transponder) chips and/or modules. These inlays may be used in secure documents, such as, but not limited to, electronic passports (ePassports), smart cards, dual interface (DI, DIF) smart cards, and electronic ID (eID) cards. Secure documents may also be referred to as “electronic documents”.

Various embodiments will be described to illustrate teachings of the invention(s), and should be construed as illustrative rather than limiting. An embodiment may be an example or implementation of one or more aspects of the invention(s). Although various features of the invention(s) may be described in the context of a single embodiment, the features may also be provided separately or in any suitable combination. Conversely, although the invention(s) may be described herein in the context of separate embodiments for clarity, the invention(s) may also be implemented in a single embodiment.

The relationship(s) between different elements in the figures may be referred to by how they appear and are placed in the drawings, such as “top”, “bottom”, “left”, “right”, “above”, “below”, and the like. It should be understood that the phraseology and terminology employed herein is not to be construed as limiting, and is for descriptive purposes only.

In the main hereinafter, antenna structures formed by mounting (which may include both embedding and laying, or “scribing”) antenna wire in substrates which are inlay substrates or card bodies for secure documents may be discussed as exemplary of various features and embodiments of the invention(s) disclosed herein. A typical pattern for the antenna formed by the antenna wire is a square spiral having and a number (such as 4 or 5) of turns, an overall length “L”, and two ends which are connected directly or indirectly (such as through conductive traces on the substrate) with corresponding two terminals of an RFID chip or chip module. Antennas which are not electrically connected with the RFID chip or chip module (but rather are inductively or reactively coupled with another antenna) may also be formed using the techniques disclosed herein.

### Some Embodiments of the Invention

The following embodiments and aspects thereof may be described and illustrated in conjunction with systems, tools and methods which are meant to be exemplary and illustrative, not limiting in scope. Specific configurations and details may be set forth in order to provide an understanding of the invention(s). However, it should be apparent to one skilled in the art that the invention(s) may be practiced without some of the specific details being presented herein. Furthermore, well-known features may be omitted or simplified in order not to obscure the descriptions of the invention(s).

### Forming Recesses in a Substrate

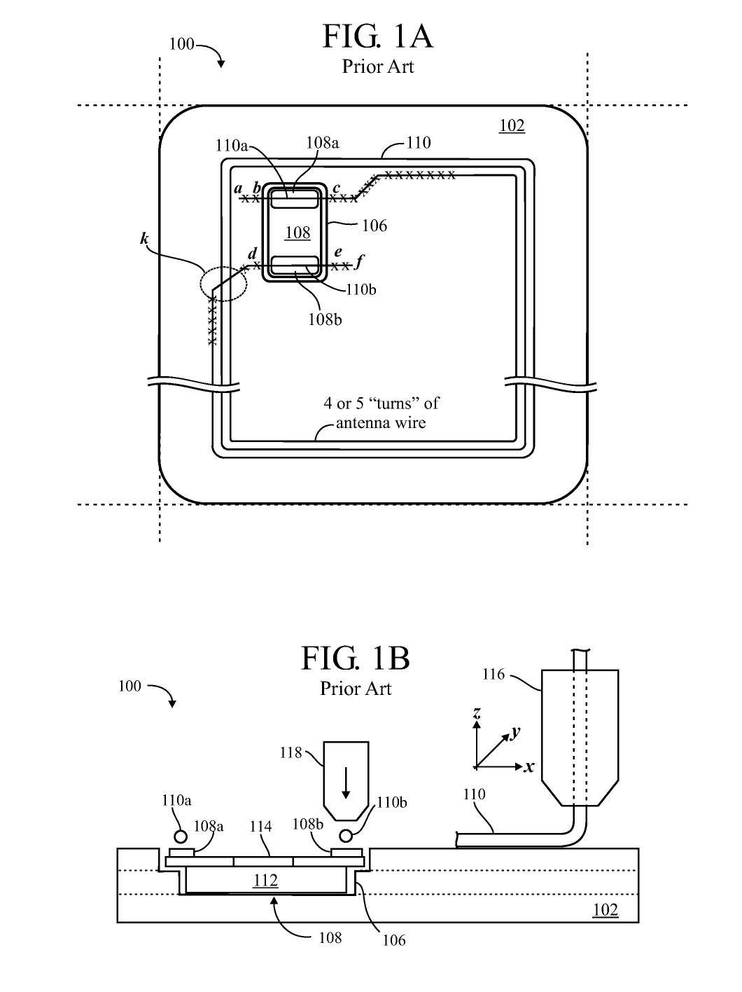

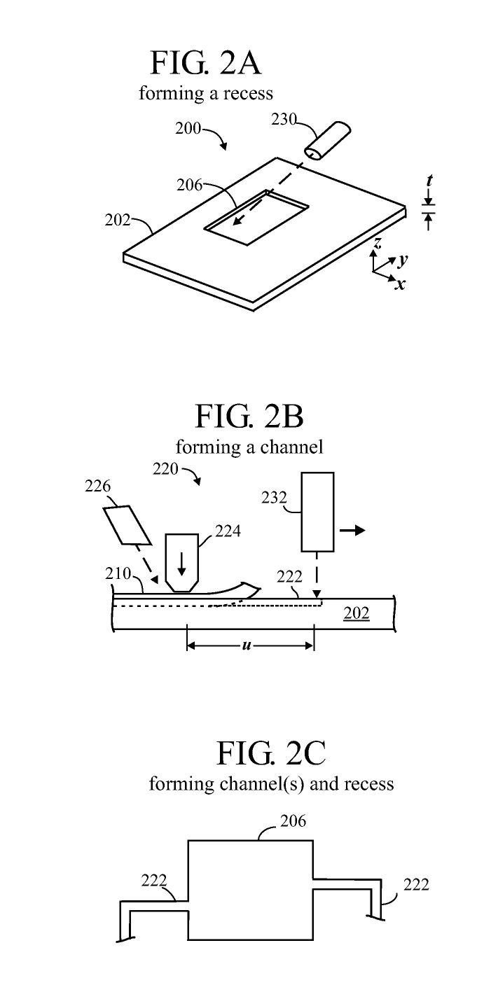

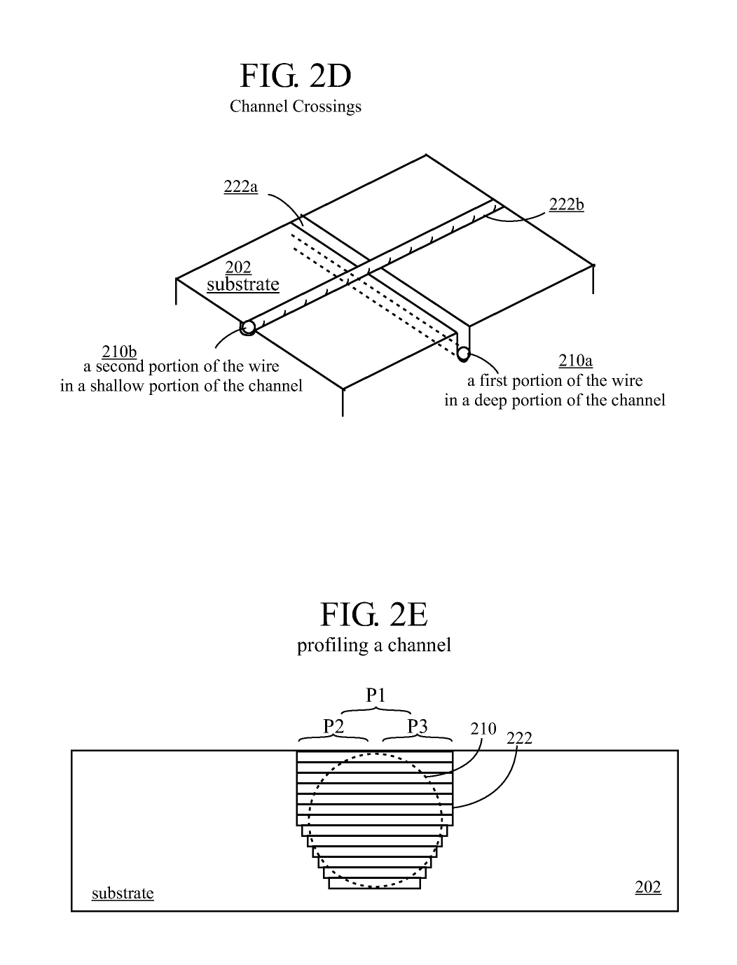

FIG. 2A illustrates a technique 200 for forming a recess 206 in a substrate 202 (such as an inlay substrate), using a laser 230. The inlay substrate 202 may be a single layer of Teslin™ (for example), having a thickness “t” of 356 μm. A typical size (width dimensions) for the recess 206, to accommodate a chip module with a lead frame, may be approximately 5 mm×8 mm. The recess may extend completely through the inlay substrate, resulting in a “window-type” recess. The recess may extend only partially, such as 260 μm through the inlay substrate, resulting in a “pocket-type” recess (FIG. 1B illustrates a pocket-type recess).

The laser 230 emits a beam (dashed line), targeted at the substrate, to ablate material from the substrate to form the recess. The beam may have a diameter of approximately 15 to 60 μm. The beam may be scanned back and forth across the recess area, making many passes to form the recess 206. Many passes may be required to carve out the entire area and depth of the recess, given that the beam diameter is typically much (such as 10-100 times) smaller than the length or width of the recess. The beam may be scanned, in any suitable manner, such as with scanning minors (galvanometer). The intensity of the beam may be controlled or modulated to control the penetration into the substrate. For example, a pulse-width modulated beam may be used. The Laser may be a UV laser (355 nm) with a power ranging from 15 to 50 watts. The process of using a laser in this manner, rather than (for example) a conventional rotating milling tool, may be referred to as “laser milling”. Laser milling can be very effective for Teslin™ and polycarbonate (PC) substrates. For Polyvinyl Chloride (PVC), laser milling is less effective. (See DE 199 15 765, 19 Oct. 2000, die Kavitäten durch laserbewirkte Thermoplastablation erzeugt werden)

### Forming Channels in a Substrate

The antenna wire may be mounted to the surface of an inlay substrate by ultrasonically embedding (countersinking) it into the surface of the inlay substrate. Ideally, the antenna wire would be fully embedded so that it is flush or below the top surface of the inlay substrate, so that the antenna not be visible (known as “witnessing the wire”) to the user in the end product. With ultrasonic embedding, the wire may become only partially embedded, and with Teslin™ it is very difficult to ultrasonically embed an antenna wire. Self-bonding wire may be used, and after mounting the wire (typically intermittently, at a sequence of points) on the substrate (and forming the turns of the antenna) the turns of the antenna may be pressed into the substrate, using heat and/or pressure, through a lamination process

FIG. 2B illustrates a technique 220 for forming a channel (groove, trench) 222 in a surface of a substrate 202 (such as an inlay substrate), using a laser 232. After the channel is formed, a wire 210 may be laid in the channel 222 using a simple pressing tool (or wheel) 224. The wire 210 may be laid into the channel 222 during formation of the channel 222, by following behind (to the left of) the laser 232 a distance “u”. Or, the wire 210 may be installed after the entire channel 222 is completed. The wire 210 may be a self-bonding (coated, self-adhering wire). By first forming channels to accept the wire in the substrate, several advantages may be realized, such as eliminating the need for the pressing operation associated with ultrasonic embedding of the antenna wire. A heating element 226 may be provided, such as a nozzle directing hot air onto the wire 210. The heating element 226 may be a laser operating in a range to heat the wire sufficiently to activate its adhesive coating.

If the diameter of the laser beam is sufficiently wide (corresponding with the desired width of the channel), and has sufficient fluence (to penetrate to the desired depth of the channel), the channel may be formed with one pass of the laser. To enhance the quality (such as texture) of the structure of the channel, it may be advantageous to use an ultrafast laser (in the picosecond or femtosecond range) using a low fluence above the threshold fluence and removing material layer by layer (several passes). At high fluence, there is a trade-off in rate of material removal and the quality of etching.

A channel 222 may be formed in a substrate with multiple passes of the laser, resulting the channel having a U-shaped or tapered profile. For example, a first pass of the laser may form a first portion of the channel having a width of approximately 100 μm (such as 97 μm) and a depth of 5 μm (dependent on the laser pulse energy and repetition rate). A second and several subsequent aligned passes of the laser may extend the previously formed portion(s) of the channel deeper, maintaining the same 97 μm width, until an intermediate channel depth of 45 or 50 μm is achieved—half of the desired overall depth of the channel. Then, maintaining alignment, in subsequent several passes the width of the laser beam may be lessened with each pass, resulting in a bottom portion (half) of the channel tapering down. In this manner, a channel can be created which has a profile (cross-section) similar to that of the wire. This may increase the opportunity for the antenna wire to stick to the walls of the channel. Alternatively, masks may be used to block portions of the laser beam and effect a similar stepwise decrease in width accompanying increase in depth.

Some exemplary operating conditions for the laser may be:
operating the laser at a pulse repetition rate of 30-40 kHz (one pulse every approximately 30 microseconds), and
the duration of each pulse may be less than approximately 10 picoseconds.

A low duty cycle (relatively short laser pulse in a relatively long interval) may be advantageous for “cold ablation”, where the material is not significantly heated. The substrate may comprise a polymer which is porous, facilitating the laser ablation, and the ablation may be performed in an inert atmosphere. Debris from the ablation process can be removed through a suction system.

FIG. 2C shows that a 2-dimensional pattern of channels 222 can be created in a substrate (not shown, such as an inlay substrate), such as using laser ablation or any other suitable process (such as gouging or molding), to accept an antenna wire (110, 210) having a number of turns or coils (such as shown in FIG. 1A). The channel(s) 222 may extend from edges of a recess 206 for accepting a chip module (108).

FIG. 2D illustrates a method of forming a pattern of channels (or portions of an overall channel) in a substrate 202 (such as an inlay substrate) to accommodate an antenna wire in a situation where the wire needs to cross over itself (such as shown in FIG. 1A), in which case insulated wire may be appropriate. A shallow channel 222a is shown crossing over a deep channel 222b. The channel 222a and 222b may be different portions of one overall channel (222). A wire 210a laid in the shallow channel 222a crosses over a wire 210b laid in the deep channel 222b. The wire 210a and 210b may be different portions of one overall wire (210). Some exemplary dimensions are:
the wire 210 may have a diameter of 80 μm
the channel(s) 222 may have a width of approximately 100 μm
the shallow channel 222a may have a depth of approximately 100 μm
the deep channel 222b may have a depth of approximately 200 μm
the substrate 202 may have a thickness of approximately 350 μm

The wire (or portion) 210b passes under the wire (or portion) 210a, without shorting thereto.

### Profiled/Tapered Channels

FIG. 2E illustrates an example of forming a channel 222 in a substrate 202. A first path “P1” is shown over a central portion of the channel 222. A second path “P2” is shown over a left portion of the channel 222. A third path “P3” is shown over a right portion of the channel 222. The order of these paths can be different.

Notice that the channel in the figure is “stepped”. This represents making several passes with the laser, at a few (such as three) widthwise positions (paths P1,P2,P3). Each pass of the laser may only remove 5 μm of material, in which case twenty (20) passes would be needed to achieve a depth of 100 μm at any given position.

The channel can be rectangular (straight sidewalls). The channel 222 can be tapered, or U-shaped. In FIG. 2E, the top half (such as upper 50 μm) of the channel 222 has straight sidewalls, and the lower half (such as bottom 50 μm) of the channel decreases in width as the depth increases, thereby the sidewalls are tapered, and approximate the semicircular profile of the bottom half of the antenna wire 210 (shown in dashed lines). This increases the contact area between the sidewalls of the channel and the antenna wire, which will enhance adhesion of a self-bonding wire in the channel.

Alternatively, masks may be used to block portions of the laser bean and effect a similar stepwise decrease in width accompanying increase in depth.

Some exemplary operating conditions for the laser may be:
operating the laser at a pulse repetition rate of 30-40 kHz (one pulse every approximately 30 microseconds)
the duration of each pulse may be approximately 30 picoseconds

This low duty cycle (relatively short pulse in a relatively long interval) is advantageous for “cold ablation”, where the material is not significantly heated.

The polymer substrate may be porous, facilitating the laser ablation, and the ablation may be performed in an inert atmosphere. Debris can be removed through a suction system.

The antenna wire may be bare (non-insulated wire). The antenna wire may be insulated wire, typically having a copper core coated with a layer of modified polyurethane (an insulating material). The antenna wire may be self-sticking wire, typically having a coating (layer) of polyvinylbutyral. The antenna wire may be insulated and self-sticking, having a coating of polyurethane covered by a coating of polyvinylbutyral. Typical dimensions for a round, insulated, self-sticking wire may be:
Diameter of copper core: 80 μm
Thickness of insulating layer of polyurethane: 4 μm
Thickness of the self-sticking layer of polyvinylbutyral: 4.5 μm

Materials other than copper may be used for the wire. Elektrisola (product name: Polysol 155) has been mentioned above. See http://www.elektrisola.com/self-bonding-wire/common-self-bonding-wire-types/iecjis.html

The pattern (turns) of the antenna wire may involve the wire crossing over itself (see FIG. 1A, “k”), in which case an insulated wire would typically be used. Using channels, such as shown in FIG. 2D, the wire may be bare wire, since one the upper channel is sufficiently higher than the lower channel that the wire in the upper channel (shallow portion of the channel) is physically separated from the wire in the lower channel (deep portion of the channel). (If the two bare portions of the antenna wire pass over each other, without touching, there is no subsequent “shorting”.) A dab of glue or other electrically insulating material may be disposed on the wire at the crossover between the two portions of wire (such as atop the lower portion). An analogy may be a bridge roadway (analogous to a portion of the wire in an upper portion of the channel) passing over a highway roadway (analogous to a portion of the wire in the lower portion of the channel.

Self-sticking antenna wire may be attached to the walls (sides and/or bottom) of the channel by means of heat (such as hot-air, ultrasonics, UV or IR light) during the process of routing the wire into the channel

Heat may be applied to ensure that the antenna wire stays in the channel, at least temporarily, such as until a cover layer is applied and adhered onto the substrate. Lamination of the cover layer onto the substrate will result in the antenna wire will be “trapped” in the channel. The cover layer may be laminated to the inlay substrate carrying the chip module and antenna wire using a hot melt adhesive, such as reactive polyurethane. With a channel having a depth slightly less than the diameter of the wire, the wire will project slightly from the substrate, and a more robust adhering of the wire to the cover layer may be achieved, providing a security feature” that the antenna will be dislodged during de-lamination (presumably for illegal purposes) of the cover layer from the substrate.

The channel for accepting the antenna wire may advertently be made wider (such as 110 μm wide rather than 100 μm wide) at selected areas along the length of the channel so that the antenna wire does not attach well at these wider sections. For example, there may be a series of wider portions, each 1 mm in length, disposed every 5 mm along the length of the channel, at least in a portion of the channel if not along the entire channel. A result of this is that the antenna wire may not stick well in these wider areas, and if an attempt is made to separate the cover layer from the inlay substrate, the antenna wire may tear out of the channel. This may be considered to be a “security feature”.

### Preparing a Surface of the Inlay Substrate for Mounting an Antenna Wire

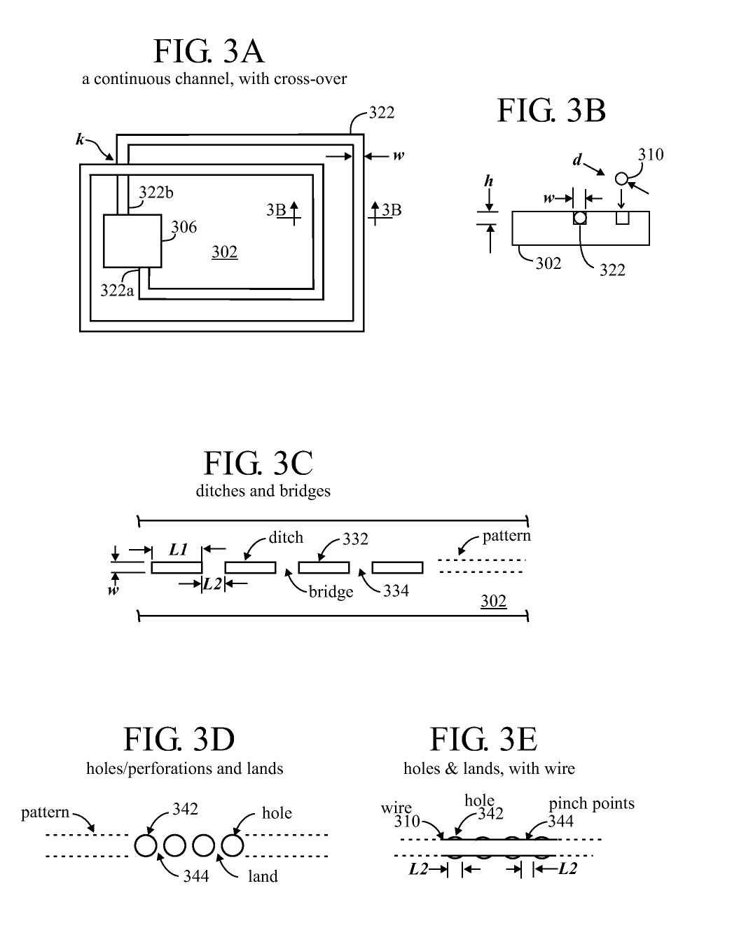

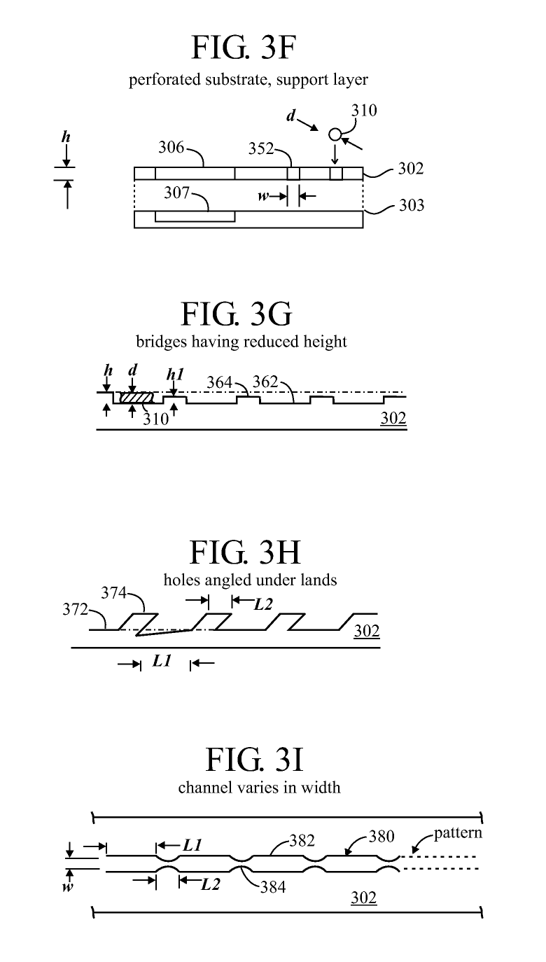

FIG. 3A illustrates a recess 306 (compare 106) formed in a substrate 302 (shown in FIG. 3B, compare 102). A chip module (not shown, compare 108) may be installed in the recess 306. A single long channel 322 (compare 222) may be formed, extending into the substrate. The channel 322 may have two ends 322a and 322b, and an overall length “L”, and is in the form of a rectangular spiral pattern having a number of turns (2 shown, 4 or 5 more typical). An antenna wire 310 (shown in FIG. 3B, compare 110) may be laid in the channel 322, with end portions of the antenna wire extending beyond the ends 322a and 322b of the channel 322 and interconnected with terminals (compare 108 and 108b) of the chip module.

FIG. 3B shows the substrate 302 in cross-section. The channel 322 has a width “w” which may be approximately equal to the diameter “d” of the antenna wire, such as approximately 80 μm (for example). The channel 322 should extend into the surface of the substrate 322 to a depth or height “h” which may be at least as great as the diameter of the antenna wire 310, so that the antenna wire 310 is entirely submerged in the substrate (to avoid “witnessing”).

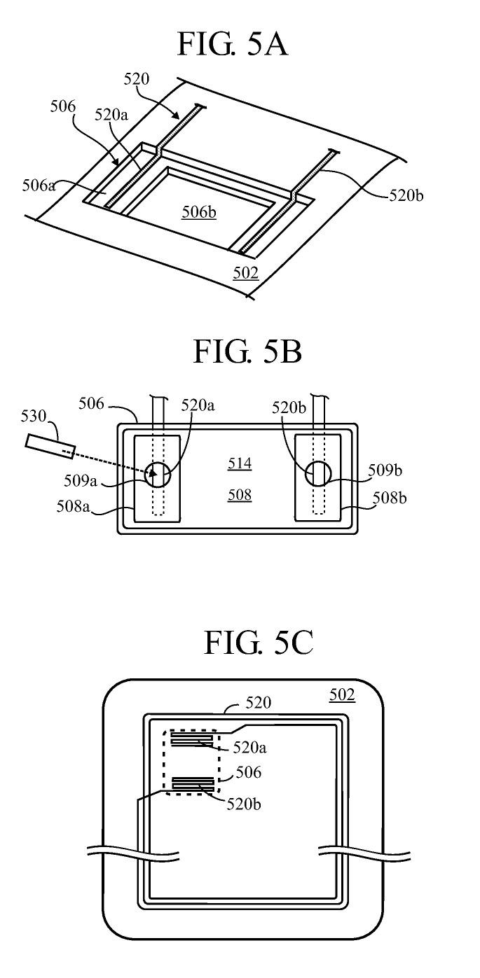

The technique shown in FIGS. 3A and 3B is similar to the technique of forming “housings” disclosed in U.S. Pat. No. 7,028,910. However, U.S. Pat. No. 7,028,910 does not disclose the channel 322 having a cross-over. (FIG. 1 of U.S. Pat. No. 7,028,910 illustrates a rectangular spiral housing/channel that has no cross-over. FIG. 2 of U.S. Pat. No. 7,028,910 illustrates a wire laid in the housing, and the wire itself crosses over inner turns of the housing pattern.) Having a cross-over (“k”, see also FIG. 1A) in a flat spiral antenna is conventional. (See, for example, FIG. 5 of U.S. Pat. No. 6,233,818.) The formation of a cross-over by having a shallow portion of a channel passing over a deeper portion of a channel is shown in and discussed with respect to FIG. 2D.

The technique of first forming a channel for receiving the antenna wire, as disclosed herein (and in U.S. Pat. No. 7,028,910) may readily be contrasted with a conventional wire embedding (or scribing) technique such as disclosed in U.S. Pat. No. 6,233,818 where inlay substrate material needs to be displaced when embedding (or subsequently pressing) the wire into the substrate which, as mentioned above, does not work well with a resistant inlay material such as Teslin™. By first forming a channel in the substrate, this problem may be alleviated. However, causing the antenna wire to stay in the channel during handling partially manufactured inlays may be a problem.

### Preparing the Substrate for Mounting the Antenna Wire

According to the invention, generally, a selected portion of the surface of a substrate corresponding to the pattern for the antenna which will be mounted to (installed in) the substrate may be prepared (treated, modified, altered) to facilitate laying/scribing/embedding the antenna wire in the substrate. Various preparation techniques are disclosed herein.

In an embodiment of the invention, the selected portion of the surface of the substrate is prepared with a plurality or series of holes or ditches (ditches are essentially elongated holes) or perforations which may be formed using laser ablation (or any other suitable process for removing material in a controlled manner from the substrate). In this manner, a significant amount of the inlay substrate material may be removed which would otherwise need to be displaced when embedding (or scribing) the wire into the substrate, such as when using an ultrasonic tool (such as wire guide, described in U.S. Pat. No. 6,233,818). Generally, the portions of the pattern where material is removed, whether holes, ditches or perforations, will be referred to hereinafter as “ditches”, unless otherwise specified or apparent from the context.

The portions of the pattern where wire will be embedded, which are not holes or ditches or perforations, which have not had material removed therefrom, are referred to as bridges or dams or lands. Generally, the portions of the pattern where material is not removed, whether bridges or dams or lands, will be referred to hereinafter as “lands”, unless otherwise specified or apparent from the context.

FIG. 3C shows an illustrative small portion of a selected area of a substrate 302 prepared with a series (sequence) of ditches 332 separated by lands (bridges) 334. This may be part of a larger rectangular spiral pattern (compare FIG. 3A) for receiving an antenna wire (compare 310) arranged in a square (rectangular) spiral pattern, for receiving an antenna wire. Four ditches 332 separated by three bridges 334 are illustrated as representative of a portion of an overall entire antenna pattern. The substrate 302 may be an inlay substrate or card body, or the like, for an electronic device such as a secure document or the like.

The “ditches” 332 are generally portions of substrate material which has been ablated (modified), much in the same manner as the single long channel 322 (FIG. 3A) may have been formed by laser ablation. The “bridges” 334 are generally portions of substrate material which has not been ablated (not modified). In contrast with the single long channel 322 shown in FIG. 3A, the overall pattern of ditches 332 and bridges 334 shown in FIG. 3C may be thought of as an “intermittent channel”. It should be understood that the “bridges” are not bridges in the conventional sense of the word, such as a bridge supported at two ends and extending over a river or a road. It should be understood that the term “bridge” is being used herein to indicate a portion of the substrate, in the pattern of the antenna, between subsequent ditches.

By way of example, a ditch 332 may have a length “L1” of approximately 1 cm, followed by a bridge 334 of substrate material having a length “L2” of approximately 1 mm, followed by the next ditch, and so forth. The ditches 332 may be elongated (longer than they are wide), and arranged generally end-to-end, but separated (spaced apart) from one another by the bridges 334. The sequence of ditches 332 establishes (or coincides with) the pattern for the antenna, such as a spiral pattern having a number of turns (see FIG. 3A).

The overall length “L” of the antenna pattern may be approximately 100 cm, indicating that there may be several, such as approximately 100 ditches (and 100 bridges) along the length of the antenna pattern and defining the antenna pattern.

The ditches 332 may have a width “w” which is approximately equal to the diameter “d” of the antenna wire, such as approximately 80 μm (for example), and should extend into the surface of the substrate to a depth “h” which is at least as great as the diameter of the antenna wire. See FIG. 3B.

When mounting the antenna wire to the substrate, the wire is laid (scribed) into the ditches 332, without significant resistance, and is resisted by the bridges 334 which will deform and retain (by interference fit) the wire at selected points along its length (along the course of the antenna pattern). (It is noted that U.S. Pat. No. 6,233,818 discussed “points of fixation of the wire conductor on the substrate”.) Generally, where the wire is mounted in a ditch, this may be referred to as “laying”, and where the wire is mounted in a bridge, this may be referred to as “embedding”, including grammatical variations of “laying” and “embedding”. FIG. 3E, discussed in greater detail hereinbelow, shows a wire being laid in holes and embedded in lands.

Generally, the ditches 332 are longer than the bridges 334. In the example above, the ditches 332 have a length “L1” of 10 mm, and the bridges 334 have a length “L2” of 1 mm, resulting in a ratio of ditch:bridge lengths (L1:L2) of approximately 10:1. Different portions of the overall antenna pattern may have different size (length) ditches and different size (length) bridges. For example, in long straight “runs” of the pattern the ditches may be very long, and near corners of the pattern the ditches may be very short. As a general proposition, the ratio of ditch:bridge lengths (L1:L2) may be at least 1:1, at least 2:1, at least 5:1, and greater than 10:1.

Some variations on “ditches and bridges” may include . . .
in some portions of the pattern, the ditches may be longer, wider, or deeper than in other portions of the pattern
in some portions of the pattern, the ditches may be curved rather than straight, etc.

FIGS. 3D and 3E illustrate removing material from the substrate in the form of a series of holes 342 rather than a sequence of ditches 332. (“Holes” may be considered to be “ditches” which have a length “L1” which is approximately equal to their width “w”. The holes 342 may be formed by laser drilling.) The holes 342 have a dimension “L1” along the surface of the substrate, in the direction of the pattern. (This is their diameter, but for consistency, the “L” terminology is employed), and may extend to a depth “h” (see FIG. 3B) into the substrate 302. The holes 342 (compare 332) are separated by unmodified portions of the substrate which are “lands” (bridges) 344. The lands 344 have a dimension “L2” along the surface of the substrate, in the direction of the pattern. As with ditches and bridges (FIG. 3C), a ratio of hole:land lengths (L1:L2) may be at least 1:1.

For illustrative clarity, the holes are illustrated having a diameter “w” which is slightly greater than the diameter “d” of the antenna wire which will be scribed into the substrate. This is also possible in practice, for example, hole diameter 100 μm, wire diameter 80 μm

As best viewed in FIG. 3E, when a wire 310 is embedded into the pattern, it easily penetrates the holes 342, and displaces the material at the lands, which become “pinch points” securing the antenna wire in the substrate 302. Here is it evident that the width “w” of the holes 342 ought to be larger than the diameter “d” of the antenna wire, else much substrate material would need to also be displaced by the wire being laid (scribed) into the holes.

The ditches 332 and holes 342 should extend into the substrate to a depth “h” which approximately equal to the diameter “d” of the antenna wire. A typical antenna wire has a diameter of 80 μm. A typical substrate may have a thickness of approximately 356 μm, and can easily accommodate ditches 332 or holes 342 having a depth of 80-100 μm. For crossovers (see “2D” in FIG. 3A) requiring a deeper ditch passing under a shallower ditch, the deeper ditch can have a depth “h” of approximately 200 μm.

Note that where the bridges 344 were (and are now collapsed as a result of the embedding process), the antenna wire 310 is held in place by an interference type fit, at the “pinch points” between the holes 342. This may advantageously obviate the need for using self-bonding wire.

The bridges between ditches (of any variety described above) will typically be shorter than the ditches, and should be as short as possible. When using an ultrasonic embedding tool (such as capillary and sonotrode), when scribing or embedding the wire into the inlay substrate, following the pattern established by the ditches, such short bridges will readily be displaced (or collapse). For example,
an antenna wire has a diameter “d” of 80 μm
the ditches have a width “w” of approximately 80 μm (w˜=d). The ditches may have a width “w” which is slightly less than (such as 60 μm) or slightly greater than (such as 120 μm) the diameter “d” of the antenna wire.
the ditches have a depth “h” of approximately 80 μm (h˜=d). The ditches may have a depth “h” which is slightly less than (such as 60 μm) or slightly greater than (such as 120 μm) the diameter “d” of the antenna wire.
the ditches each have a length “L1” of approximately 10 mm.
the lands between adjacent ditches each have a length “L2” of approximately 1 mm
the lands may have a height which is approximately equal to the depth “h” of the ditches. (The height of a land may be measured from the bottom of the ditches which it separates.)

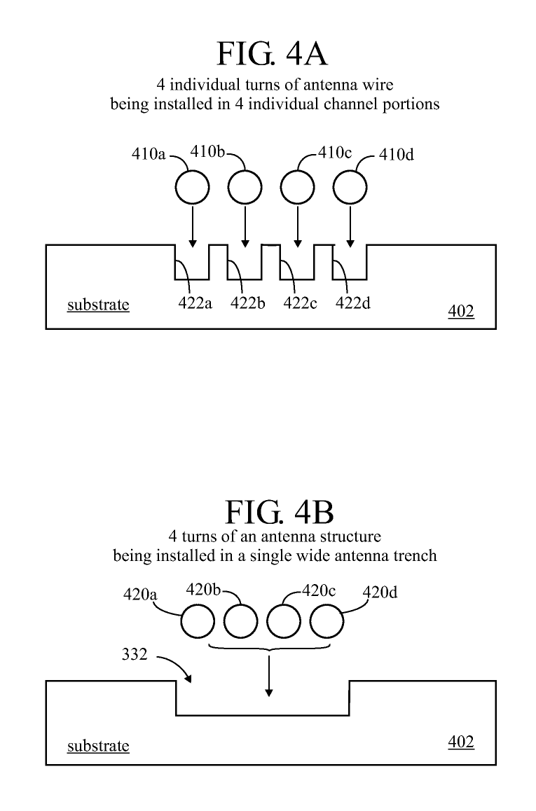

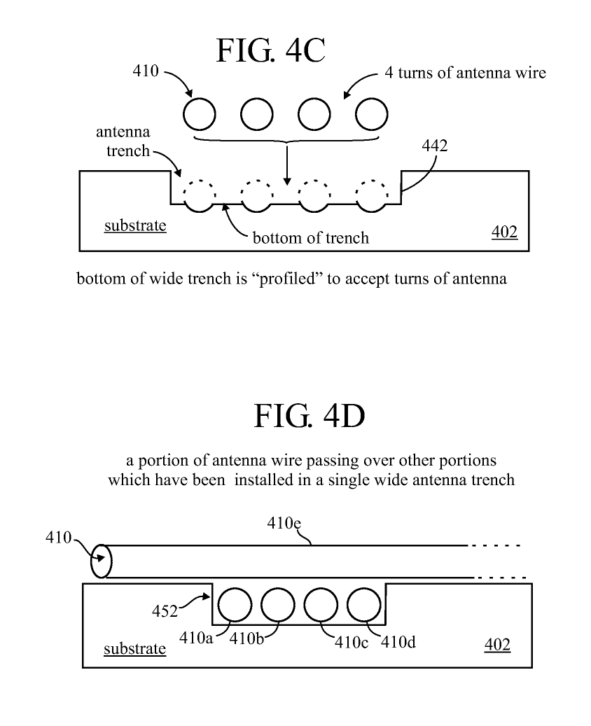

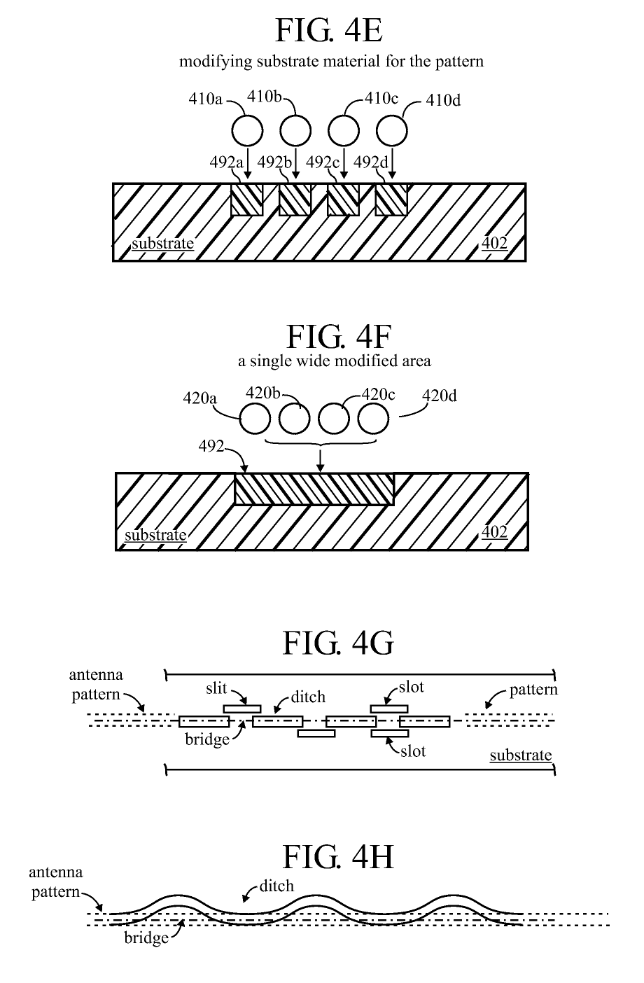

In some variations of removing material from selected portions of the substrate to facilitate embedding the antenna wire in the pattern,
the lands (bridges) between adjacent ditches are reduced in height by removing some material therefrom, such as by laser ablation, such as to have a resulting height “h1” which is slightly less than the diameter “d” of the antenna wire. This is discussed with respect to FIG. 3G.
ditches which are holes extend at an angle into the substrate, thereby undermining the lands, which will facilitate embedding the antenna wire in the lands. This is discussed with respect to FIG. 3H.
rather than having distinct ditches and lands, the pattern for the antenna is prepared by removing material in an undulating manner, and embedding the antenna wire in the substrate where the undulating pattern of the ditch deviates from the antenna pattern. This is discussed with respect to FIG. 4H.

### Some Variations on Ditches and Bridges

FIG. 3F illustrates a multi-layer substrate having a top layer 302 and a bottom layer 303. The top layer may have a thickness “h” of approximately 100 μm, the bottom layer 303 may have a thickness of approximately 250 μm. Ditches (or holes) 352 may be formed extending entirely through the top substrate layer 302, and may be considered to be “perforations”. A recess 306 for the chip module (308) may be formed extending entirely through the top substrate layer 302. A corresponding recess 307 may be formed extending partially through the bottom substrate layer 303. In this manner, the top substrate layer 302 may be prepared with perforations 352 for receiving the antenna wire (310) and a recess 306 for receiving the chip module (308) using mechanical means such as simply by punching out the perforations 352 and the recess 306. Later, prior to installing the antenna wire (310) and the chip module (308), the bottom support layer 303 may be added, disposed under the substrate 302, and may be laminated thereto.

FIG. 3G illustrates a substrate 302 prepared with ditches (or holes) 362 and bridges (lands) 364. In this example, the lands 364 are modified such as trimmed down (reduced in height) so that they will be easier to displace when the antenna wire 310 is installed into the pattern. The ditches 362 have a depth “h”. The bridges 364 have a reduced height “h1”. As before, the depth “h” of the ditches 362 may be approximately equal to the diameter “d” of the antenna wire 310. The height “h1” of the bridges 364 should be at least half the diameter “d” of the antenna wire 310, so that the wire can be secured at the “pinch” points at its widest chord, its diameter. For example, the bridges can be trimmed down so that “h1” is 60-75% of “h”. As an alternative to trimming down the height of the bridges 364, they can be slotted or otherwise modified or deformed to be more amenable to wire embedding.

FIG. 3H illustrates a substrate 302 prepared with ditches (or holes) 372 and bridges (lands) 384. In this example, the ditches 372 extend at an angle into the substrate 302 so that they extend at least partially under the bridges 374. This undermines the bridges 354, which may make them easier to displace (facilitating their collapse) when the antenna wire (310) is installed in the pattern. Also illustrated (in one of the ditches illustrated), the bottoms of the ditches 372 may be profiled and extend further into the substrate 302 than otherwise necessary so that when the adjacent bridge is deformed by wire installation, there is space at the bottom of the ditch to receive the collapsed bridge.

FIG. 3I illustrates a variation of the techniques set forth above wherein a single long channel 380 (compare 322, FIG. 3A), only a small portion of which is shown, is formed by removing material (such as by using laser ablation) in the pattern of the antenna. Rather than having ditches (322, FIG. 3C) and bridges (324, FIG. 3C), the channel 380 has alternating areas 382 where material is removed and areas 384 where material is not removed. This is conceptually comparable to the alternating ditches 322 and bridges 324 shown in FIG. 3C. The areas 382 may have a width “w” which is slightly greater than the diameter “d” of the wire, and the areas 384 may have a width “w” which is slightly less than the diameter “d” of the wire. The narrower areas 384 will form “pinch points” (compare FIG. 3E) when the wire is laid in the channel 380.

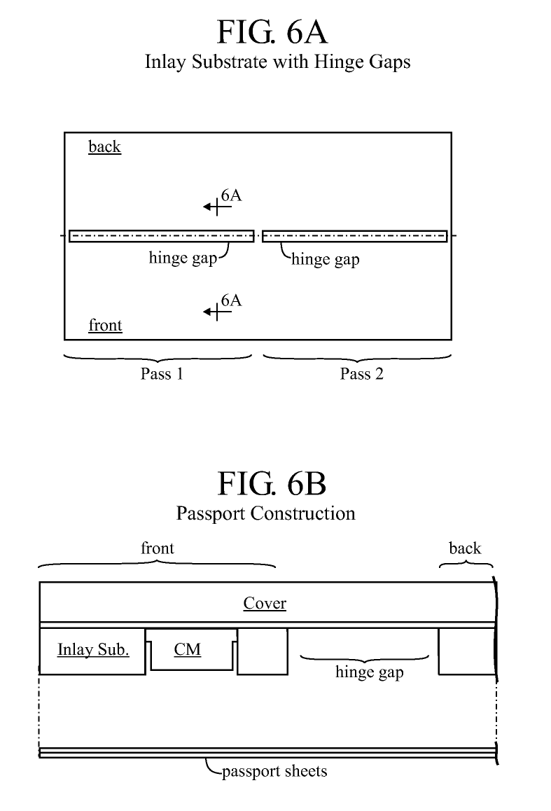

The channels, ditches, holes, recesses discussed above, and hinge gaps discussed below (see FIGS. 6A, 6B) in substrates disclosed herein may be ablated with a nanosecond (ns), picosecond (ps) or femtosecond (fs) laser operating at UV (ultraviolet), VIS (visible) or IR (infrared). The substrate may be a polymer, such as porous (Teslin™) or non-porous (polycarbonate) or can be doped to facilitate the laser ablation process. The ablation can take place in an inert atmosphere and the polymer can be heated or chilled prior to laser treatment. Laser ablation is particularly good with a porous polymer, as its porosity facilitates the ablation process.

In some embodiments of the invention discussed below, for example with respect to FIGS. 4E and 4F, rather than removing material to form ditches or holes, the selected portion of the surface of the substrate for the antenna pattern is prepared by altering its embedability, such as by irradiating with a laser to soften the material in and optionally around (adjacent) the antenna pattern to facilitate wire embedding.

### Installing Antennae in Channels or Trenches

FIG. 4A shows four individual portions 410a, 410b, 410c, 410d such as four turns of an antenna wire (410) being inserted (installed, mounted) into corresponding four individual portions 422a, 422b, 422c, 422d of a channel (422) or channels in a substrate 402 (such as an inlay substrate). Each portion of the wire may be inserted (laid) sequentially (turn-by-turn) into the corresponding channel portion as the turns of the antenna are formed on the substrate, such as using an ultrasonic tool. The channel (422) may be formed by laser ablation. A completed antenna may be referred to as an “antenna structure”, such as described in the next figure. Terminal ends (connection portions) of the antenna structure may be connected with corresponding terminal areas of a chip module disposed in an inlay substrate. (In this and other drawings, the antenna structure is illustrated comprising several turns of a wire spaced apart from one another, forming a “flat coil” configuration. The spacing may be much greater than shown, such as 10-20 times the wire diameter.)

FIG. 4B shows a single, wide antenna trench (or channel, or groove) 432 formed in a substrate 402 (such as an inlay substrate). An antenna structure (420) having four turns 420a, 420b, 420c, 420d of antenna wire (a flat coil) is shown being disposed (installed into) the wide antenna trench 432. The antenna trench 432 may be several times wider than the diameter (or cross-dimension) of the wire (the wire need not have a round cross-section), so that the single wide antenna trench can accommodate the multiple turns of an antenna structure. For example, four turns of 80 μm wire, spaced 40 μm apart from one another, in a 450 μm wide antenna trench 422. The wide antenna trench 432 should have a depth (into the substrate) which is approximately equal to the diameter “d” of the wire forming the antenna structure (420) so that the flat coil of the antenna structure (420) will be recessed at least flush within the trench, not protruding above the front surface of the substrate after it is installed. The trench (which is essentially a wide channel) may be formed by laser ablation. Typically, the turns of the antenna structure (420) would be spaced slightly apart from one another.

The turns of the antenna structure (420) may be laid (scribed) into the trench sequentially (turn-by-turn) using an ultrasonic sonotrode tool (such as in U.S. Pat. No. 6,233,818). Alternatively, the antenna structure can be preformed, and disposed as a single unit into the wide trench. In conjunction with laying the antenna structure (420) in the trench (whether turn-by-turn or as a single unit), connection portions (ends, end portions) of the antenna being formed in the trench may be connected to terminals of a chip module.

Terminal ends (connection portions, ends, end portions) of a preformed antenna structure wire may be connected to terminals of the chip module (not shown) prior to installing the antenna structure in the wide antenna trench. Installing an antenna structure with chip module onto a substrate is disclosed in U.S. Pat. No. 5,809,633 (Mundigl), incorporated by reference herein.

Glue may be dispensed in the wide antenna trench, such as the entire width of an antenna structure which may be formed (embedded) or placed (such as transferring an antenna structure, described below) into the antenna trench. The trench to accept an antenna structure may be partially filled with adhesive. Alternatively, a layer of adhesive could be disposed over the entire area of the inlay substrate covering (entering) both the trench for the antenna structure and the recess for the chip module. In placing the chip or chip module in its (laser ablated) recess, the adhesive may act as an anti-fretting medium to reduce the risk of micro-cracking especially in polycarbonate (PC) cards.

As an alternative to using wire, copper foil(s), such as punched (stamped) metallic foils may be laid into the antenna trench 432. A ribbon (such as copper) may be used. Conductive material disposed in channels (such as laser-ablated channels) may also be used. A process involving the selective deposition and formation of copper layers is described at the website http://www.kinegram.com/kinegram/com/home.nsf/contentview/˜kinegram-rfid, incorporated by reference herein.

### Profiling the Bottom of the Wide Antenna Trench

FIG. 4C is a cross-sectional view of an inlay substrate 402 having an antenna trench 442, and an antenna with 4 turns of antenna wire 410 being disposed (installed into) the trench. The trench 442 has a width “w” (across the page) which is at least 4 times wider than the diameter of a given wire (more like 5 times as wide allowing for some spacing between adjacent turns of the wire) and has a depth “h” (into the substrate, from a front surface thereof) which is approximately equal to the diameter “d” of the wire so that the flat coil of antenna wire will be flush within the trench, not protruding above the front surface of the substrate after it is installed.

Connection portions (ends, end portions) of the antenna wire 410 may optionally be connected to terminals of the chip module (not shown) prior to installing the antenna in the trench (thus, the antenna and chip module would be installed together, as in U.S. Pat. No. 5,809,633), or the antenna wire 410 may be laid in the trench and connected to the terminals of a chip module (not shown, compare 108) previously installed in the substrate 402.

In this embodiment, the bottom surface of the antenna trench 442 is profiled, or grooved, to better conform to the round cross-section of the turns of wire 410 which will be laid in the trench, thereby providing more surface contact area between the bottom of the trench and the turns of antenna wire.

Alternatively, the bottom of the wide trench may be textured, having an irregular or fuzzy topology to assist in “capturing” an antenna structure formed with self-bonding wire which may be transferred as a completed antenna structure into the wide trench in the inlay substrate.

The bottom of the trench illustrated herein is not the surface (or side) of the substrate. The grooves, or depressions, may extend only a portion of the diameter of the wire into the bottom of the trench, and should be distinguished from grooves or channels for accepting individual turns of antenna wire such as described hereinabove, or in U.S. Pat. No. 7,028,910 (Schlumberger), where grooves having a depth substantially equal to (or greater than) the diameter of the wire are formed in the surface of the substrate (in Schlumberger, “housings” extend into the “side” of the substrate).

FIG. 4D shows a single, wide antenna trench (or groove) 422 formed in a substrate 402. The substrate 402 may be an inlay substrate for a transponder. Four portions 410a, 410b, 410c, 410d of an antenna wire 410 are shown installed in the trench 422. The antenna wire 410 may alternatively comprise tracks or traces of conductive material (other than wire) including nanoparticles, nanotubes and nanowires disposed in the trench. In either case, the wire or conductive material of the antenna disposed within the trench 422 are suitably disposed below the surface of the substrate 402.

Another portion 410e of the wire (or conductive trace) extends along the surface of the substrate 402 (the trace is shown slightly separated from the substrate, for illustrative clarity), and passes over the other portions 410a-410d of the antenna conductor 410 without shorting thereto (compare FIG. 1A, crossover “k”). The possibility of a portion (410e) of the wire being on the surface of the substrate and passing over submerged portions (410a-410d) of the wire is also discussed with respect to FIG. 2D.

### Modifying the Substrate Material in the Area of the Antenna Pattern

FIG. 4E (similar to FIG. 4A) illustrates the concept that a selected portion of a substrate 402 may be treated to facilitate (in preparation for) wire embedding, without altering or compromising qualities of the remaining, untreated portion of the substrate. In the examples described with respect to FIGS. 3C-3H, a pattern for the antenna wire is established by a removing material to form a sequence of ditches and bridges, in a pattern for the antenna, to facilitate embedding or scribing an antenna wire into the substrate. (FIGS. 3A and 3I also disclose removing material from the substrate to form a continuous channel.) In this embodiment, rather than removing material from the substrate to form ditches and bridges, the physical properties of the substrate are altered, without removing material, in a pattern for the antenna, to facilitate embedding or scribing an antenna wire into the substrate.

FIG. 4E shows four individual portions 410a, 410b, 410c, 410d such as four turns of an antenna wire (410) being inserted into corresponding four individual portions 492a, 492b, 492c, 492d of an antenna pattern (492) in a substrate 402 (such as an inlay substrate). Each portion of the wire may be inserted (laid) sequentially (turn-by-turn) into the corresponding pattern portion as the turns of the antenna are formed on the substrate, such as using an ultrasonic tool.

The portions 492a, 492b, 492c, 492d of the antenna pattern (492) may be formed by laser treatment, ranging from simply warming the selected portions to locally modifying the physical structure of the selected portions, such as crystallizing or disassociating the substrate material.

The portions 492a, 492b, 492c, 492d of the antenna pattern (492) have a nominal width “w” approximately equal to the diameter “d” of the antenna wire (410), and a depth “h” at least as great as the diameter “d” of the antenna wire (410). Since the portions 492a, 492b, 492c, 492d of the antenna pattern (492) are close to one another, they may be “merged together” as shown in the next figure.

FIG. 4F (similar to FIG. 4B) shows a single, wide portion or area 494 of a substrate 402 (such as an inlay substrate) which is modified to accept an antenna structure (420) having four turns 420a, 420b, 420c, 420d of antenna wire (a flat coil). The area 494 may be several times wider than the diameter (or cross-dimension) of the wire (the wire need not have a round cross-section), so that the single wide antenna-receiving area 494 can accommodate the multiple turns 420a,b,c,d of the antenna structure. For example, four turns of 80 μm wire, spaced 40 μm apart from one another, in a 450 μm wide prepared area 494. The area 494 should have a depth (into the substrate) which is approximately equal to the diameter “d” of the wire forming the antenna structure (420), to facilitate embedding the antenna to be recessed at least flush within the substrate, not protruding above the front surface of the substrate after it is installed.

In the embodiments of FIGS. 4E and 4F, simply roughing up the surface of the substrate in the area of the antenna pattern may be sufficient to achieve the desired benefit of facilitating embedding the antenna wire in a difficult to embed substrate (such as Teslin).

There have thus been shown various surface preparations that are not channels. This includes trenches and bridges (as shown above) and modifying the material of the substrate without removing it. Other surface preparations may be used to facilitate mounting the antenna wire, such as a waffle pattern, or hybrid approaches utilizing various of the features described above.

as noted in our S41pct, the wide trench is very useful for a residual web of antenna substrate (between the turns of the wire) being transferred along with the antenna (perforations in antenna substrate around outer periphery of antenna structure on antenna substrate)

### A “Hybrid” Approach

A motivation for some of the embodiments disclosed herein is avoiding infringing U.S. Pat. No. 7,028,910 (Schlumberger), the benefits of avoiding infringing being “legal”. In some of the embodiments, some actual technical benefits may accrue, for example regarding the “pinch points” (FIG. 3E) which hold the antenna wire more securely in place (than a channel) during handling the substrate.

In FIGS. 2B-2E, 3A-3I, 4A-4D material is removed from the substrate coincident with the pattern of the antenna. In FIGS. 4E, 4F material coincident with the pattern of the antenna is modified, rather than removed.

FIG. 4G (compare FIG. 3C, for example) shows another variation of a technique for mounting an antenna wire in an inlay substrate (or card body). An exemplary portion of the antenna pattern is shown, which may be one of the several straight portions of a square spiral antenna pattern (compare FIG. 3A). A number of ditches are separated by bridges. In the manner described above (FIG. 3C), wire may be laid in the ditches, and embedded into the bridges. To facilitate the collapse of the bridges (displacement of material when embedding antenna wire into the bridges), some material may be removed from the substrate adjacent the bridges, such as in the form of slits (or slots) disposed alongside the bridges to facilitate their collapse/displacement. The slits/slots may be disposed on either side of, or on both sides of the pattern. Functionally, the addition of slits/slots serves a similar purpose making the bottoms of ditches deeper to accommodate displacement of bridge material during embedding (compare FIG. 3H).

FIG. 4H shows another variation of a technique for mounting an antenna wire in an inlay substrate (or card body). In this example, the channel is continuous, but follows a “serpentine” path which is alternately coincident with and adjacent to the antenna pattern. A locations where the channel is coincident with the antenna pattern, these portions of the channel function as “ditches” within which the antenna wire can easily be laid. A locations where the channel is not coincident with the antenna pattern, but rather is adjacent the antenna pattern, these portions of the channel function as “bridges” within the wire can be embedded. The approach in FIG. 4H is similar to the “baseline” embodiment of alternating bridges and ditches shown in FIG. 3C, with alternating laying and embedding of the wire. The approach in FIG. 4H may also be likened to a “smoothed out” version of FIG. 4G with the non-coincident (with the antenna pattern) portions of the serpentine channel functioning like the slits and slots shown in FIG. 4G facilitating displacement of substrate material when there is no ditch.

The techniques disclosed or suggested herein for preparing an area of the substrate for mounting an antenna by removing material or modifying material may be combined in a technique for removing and modifying material.

### Some Applications, Products and Components for Secure Documents

FIGS. 5A, 5B illustrate an inlay substrate 502. A stepped pocket recess 506 for a chip module 508 is formed in a substrate 502 and has an upper wider portion 506a for the leadframe 514 (compare 114) of a chip module 508 (compare 108) and a lower narrower portion 506b for the mold mass (compare 112) of the chip module 508. A conductive track which may be a wire or conductive material disposed in a channel forms an antenna 520 having termination ends 520a, 520b extending into the recess 506 and across the bottom portion 506b thereof. If a self-bonding wire is used, insulation may be removed from the termination ends 520a, 520b to facilitate connecting to terminal areas 508a, 508b of the leadframe 514 of the chip module 508. As best viewed in FIG. 5B, holes 509a, 509b are formed through the terminal area 508a, 508b of the leadframe 514. The holes 509a, 509b may be micro holes which are percussion drilled into the metal leadframe 514 of the chip module 508 at each terminal area 509a, 509b to allow for the welding (such as with a laser 530), soldering or crimping of the leadframe terminals to the respective termination ends 520a, 520b of the antenna 520. When the chip module 508 is installed in the recess 506, the terminal ends 520a, 520b of the antenna (wire) 520 will be connected on the same side of leadframe as the mold mass

FIG. 5C illustrates an inlay substrate 502 having a conductive trace forming an antenna 520 having two termination ends 520a, 520b. The antenna 520 may be an antenna structure preformed on an antenna substrate and transferred to the inlay substrate. The inlay substrate 502 may comprise various laminated sheets, may be of a synthetic material such as PVC, may be in credit card format and may have a thickness of approximately 250 μm (microns). The antenna 520 may be a HF antenna with a number of turns (compare 110).

End portions (or termination ends) 520a, and 520b of the antenna 520 may be formed with squiggles or meanders to provide an area of increased surface area for receiving and being connected with terminal areas attachment of a chip module (such as a dual-interface (DI) chip module). These squiggles or meanders may be considered to be “contact areas”, and are generally located on opposite sides of a transponder site 506 (shown in dashed lines) on the surface of the substrate 502 where a chip module (not shown) will be mounted. The substrate 502 with antenna 520 already embedded may be provided in reel or sheet form, as a component for manufacture of a secure document.

Substrate components for electronic devices may prepared with ditches and bridges, or any of the techniques disclosed herein, and supplied to users who desire to mount the antenna wire themselves. An antenna wire component may also be supplied to the user, and may be an insulated wire which has had the insulation removed at selected areas whereat the antenna wire will be bonded to terminals of the chip or chip module.

### Forming a Hinge Gap in an Inlay Substrate

FIGS. 6A, 6B illustrate a technique for forming a hinge gap in a substrate (such as an inlay substrate), using a laser. The illustrated inlay substrate is prepared for two passports (Pass 1, Pass 2) and may comprise a single layer of Teslin™ (for example), having a thickness “t” of 356 μm. Hinge gaps are formed in the inlay substrate between the front and back portions of the inlay substrate. A typical size (width dimensions) for the hinge gap, to accommodate the pages of a passport booklet, may be approximately 10 mm×275 mm. The hinge gap may extend completely through the inlay substrate, resulting in a “window-type” hinge. The hinge gap may extend only partially, through the inlay substrate, resulting in a “pocket-type” hinge. A chip module (CM) is illustrated in a recess in the inlay substrate. Reference is made to US 2011/0155811, incorporated by reference herein.

While the invention has been described with respect to a limited number of embodiments, these should not be construed as limitations on the scope of the invention, but rather as examples of some of the embodiments. Those skilled in the art may envision other possible variations, modifications, and implementations that are also within the scope of the invention, based on the disclosure(s) set forth herein.

What is claimed is:

1. A method of mounting a wire to a substrate for an electronic device comprising:
preparing a selected area of the substrate with a sequence of ditches, separated by bridges, thereby removing material at some locations where an antenna wire will be scribed into the substrate; and
scribing the antenna wire into ditches and embedding the antenna wire into the bridges.

2. The method of claim 1, wherein:
the ditches coincide with a pattern for an antenna formed by the wire.

3. The method of claim 2, wherein:
the pattern is a spiral pattern having a number of turns.

4. The method of claim 1, wherein:
the ditches are elongated, being longer than they are wide.

5. The method of claim 1, wherein:
the ditches are arranged generally end-to-end, but spaced apart from one another by the bridges.

6. The method of claim 1, wherein:
the ditches have a length (“L1”);
the bridges have a length (“L2”); and
the ditches are longer than the bridges.

7. The method of claim 6, wherein:
the ditches are at least twice as long as the bridges.

8. The method of claim 6, wherein:
the ditches are approximately ten times long as the bridges.

9. The method of claim 1, wherein:
the ditches are in the form of a series of holes, separated by bridges which are lands.

10. The method of claim 1, wherein:
the substrate is a multi-layer substrate having a top layer and a bottom layer;
the ditches extend completely through the top layer of the substrate.

11. The method of claim 1, wherein:
the ditches have a depth (“h”) which is approximately equal to a diameter (“d”) of the wire.

12. The method of claim 1, wherein:
the ditches have a depth (“h”);
the bridges have a height which is approximately equal to the depth of the ditches.

13. The method of claim 1, wherein:
the ditches have a depth (“h”);
the bridges have a height (“h1”) which is less than the depth of the ditches.

14. The method of claim 1, wherein:
the ditches extend at least partially under the bridges.

15. The method of claim 1, further comprising:
removing material from the substrate adjacent the bridges.

16. The method of claim 1, wherein a serpentine channel is formed in the surface of the substrate, and wherein:
first portions of the serpentine channel function as channels into which the wire can be laid; and
second portions of the serpentine channel function as bridges into which the wire can be embedded.

17. The method of claim 1, wherein the electronic device is a transponder.

18. The method of claim 1, wherein the substrate is an inlay substrate or card body for a secure document.

19. The method of claim 1, wherein the bridges collapse when mounting the wire, and the collapsed bridges form pinch points for securing the wire in the substrate.

20. A substrate prepared with ditches and bridges, according to claim 1.
